(19) United States
(12) Patent Application Publication
(10) Pub. No.: US 2007/0277957 A1
(43) Pub. Date: Dec. 6, 2007

(54) HEAT SINK

(75) Inventors: HUNG-YI WU, Tu-Cheng (TW); Zhen-Xing Ye, Shenzhen (CN)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Tu-Cheng (TW)

(21) Appl. No.: 11/309,486

(22) Filed: Aug. 11, 2006

(30) Foreign Application Priority Data
Jun. 2, 2006 (CN) 200610060968.9

(51) Int. Cl. H05K 7/20

(52) U.S. Cl. 165/80.3; 361/704

(57) ABSTRACT

A heat sink includes a base and a plurality of parallel fins extending up from the base. The heat sink has an air inlet and an air outlet. A thickness of the base gradually reducing from a middle of the base to both sides nearby the air inlet and the air outlet.

### 1. FIELD OF THE INVENTION

The present invention relates to heat sinks, and more particularly to a heat sink having high heat dissipation efficiency.

### 2. DESCRIPTION OF RELATED ART

Advances in microelectronics technology have caused electronic devices, which process signals and data, at unprecedented high speeds. During operation of many contemporary electronic devices, such as CPUs (Central Processing Units), large amounts of heat are produced. The heat must be efficiently removed, to prevent the system from becoming unstable or being damaged. Heat sinks are frequently used to dissipate heat from these electronic devices.

Referring to FIG. 3 and FIG. 4, a conventional heat sink 10 includes a base 12, and a plurality of parallel fins 14 extending up from the base 12. The base 12 is a tablet shaped metal block with flat top and bottom surfaces. The heat sink 10 is configured for being attached to an electronic device (not shown), such as a CPU, for heat dissipation. That is, the bottom surface of the base 12 clings to the electronic device.

A fan (not shown) is set, to assist in heat dissipation, at one side of the heat sink 10 with a certain distance from the heat sink 10. Airflow from the fan enters the heat sink 10 through an air inlet 13 of the heat sink 10, and exits from an air outlet 15 of the heat sink 10. The airflow includes a first airflow 110 passing through the fins 14, a second airflow 112 passing across the bottom surface of the heat sink 10 and sides of the electronic device, and a third airflow 114 passing across a side 120 of the base 12. The third airflow 114 produces vortexes when passes across the side 120 of the base 12 because of a certain thickness of the base 12. Thus, the third airflow 114 is impeded, and resistance of the airflow increases when passing through the heat sink 10, thereby reducing heat dissipation of the heat sink 10.

What is desired, therefore, is a heat sink which provides high efficiency of heat dissipation.

### SUMMARY OF THE INVENTION

In one preferred embodiment, a heat sink includes a base and a plurality of parallel fins extending up from the base. The heat sink has an air inlet and an air outlet. A thickness of the base gradually reduces from a middle of the base to both sides nearby the air inlet and the air outlet.

Other advantages and novel features will become more apparent from the following detailed description of preferred embodiments when taken in conjunction with the accompanying drawings, in which:

### BRIEF DESCRIPTION OF THE DRAWINGS

FIG. 1 is an isometric view of a heat sink, in accordance with a preferred embodiment of the present invention;

FIG. 2 is a front view of FIG. 1;

FIG. 3 is an isometric view of a conventional heat sink; and

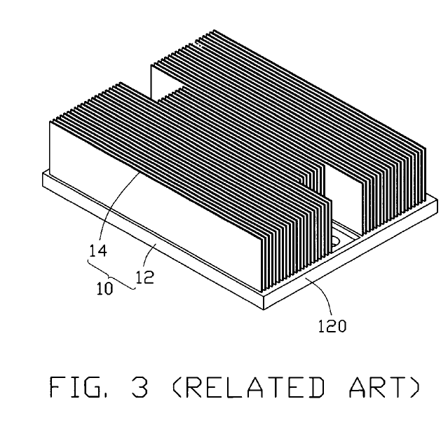

FIG. 4 is a front view of FIG. 3.

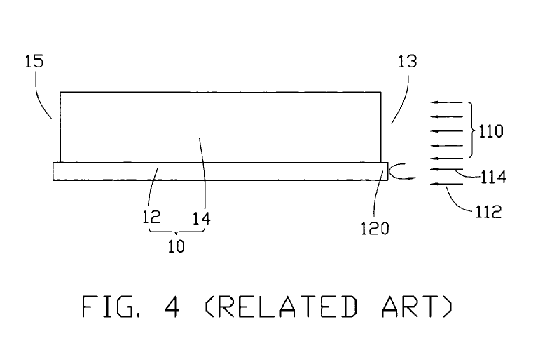

### DETAILED DESCRIPTION OF THE INVENTION

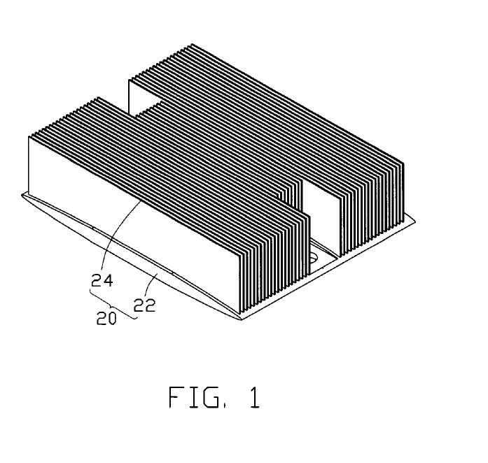

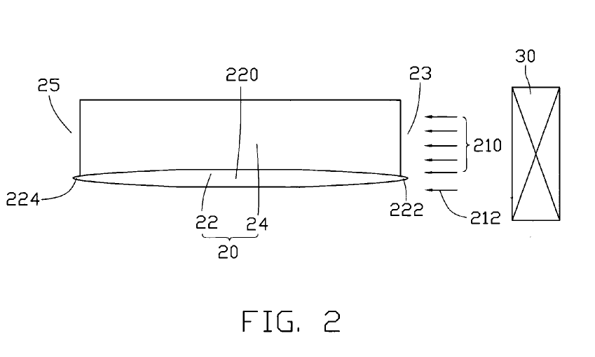

As shown in FIG. 1 and FIG. 2, in a preferred embodiment of the present invention, a heat sink 20 includes a heat-conductive base 22, and a plurality of parallel fins 24 extending up from the base 22. Every two adjacent fins 24 are spaced from each other with a passage formed therebetween. The passage has an air inlet 23 at one side 222 of the heat sink 20 and an air outlet 25 at an opposite side 224 of the heat sink 20. A thickness of the base 22 gradually reduces from a middle portion 220 of the base 22 to the opposite sides 222, 224 of the base 22.

An airflow generating device, such as a fan 30 is set, to assist in heat dissipation, at a certain distance from the heat sink 20. Airflow from the fan 30 enters the heat sink 20 through the air inlet 23 of the heat sink 20, and exits from the air outlet 25 of the heat sink 20. In profile the base 22 is wing-shaped or generally in a shape of a flattened ellipsoid. The base 22 has a top surface and a bottom surface. The bottom surface of the base 22 includes a planar part in a middle thereof configured for attachment to an electronic device, and two curved portions extending from opposite sides of the planar part of the bottom surface towards the top surface respectively. For example the planar part may be substantially flat to match a shape of a top surface of the electronic device. The top surface of the base 22 is arc shaped and higher in a middle thereof. The top surface of the base 22 includes a planer part thereof, and two curved portions extending from opposite sides of the planer part of the top surface of the base 22 towards the bottom surface respectively. The top surface and the bottom surface of the base 22 form intersecting lines nearby the air inlet 23 and the air outlet 25.

In use, the heat sink 20 is attached to the electronic device, such as a CPU, for heat dissipation. A top surface of the electronic device is located under, and attached to, the planar part of the bottom surface of the base 22.

The airflow from the fan 30 includes a first airflow 210 passing through the passage between the fins 24 of the heat sink 20, and a second airflow 212 passing along the bottom surface of the base 22 and sides of the electronic device. Because of the base 22 being wing shaped and the thickness of the base 22 gradually reducing from the middle portion 220 of the base 22 to the sides 222, 224 of the base 22, resistance of the airflow is minimized. Therefore, this aerodynamic design allows better airflow through the heat sink 20.

It is to be understood, however, that even though numerous characteristics and advantages of the preferred embodiments have been set forth in the foregoing description, together with details of the structures and functions of the embodiments, the disclosure is illustrative only, and changes may be made in detail, especially in matters of shape, size, equivalent material and arrangement of parts within the principles of the invention to the full extent indicated by the broad general meaning of the terms in which the appended claims are expressed.

What is claimed is:

1. A heat sink comprising:
a heat-conductive base being wing-shaped and including a top surface and a bottom surface; a thickness of the base gradually reducing from a middle of the base to both sides nearby the air inlet and the air outlet; and
a plurality of parallel fins extending up from the top surface of the base, every two adjacent fines being spaced from each other with a passage formed therebetween, and the passage having an air inlet at one side of the heat sink and an air outlet at an opposite side of the heat sink.

2. The heat sink as claimed in claim 1, wherein the bottom surface of the base includes a planar part in a middle thereof, and two portions extending slantingly from opposite sides of the planar part of the bottom surface towards the top surface respectively.

3. The heat sink as claimed in claim 1, wherein the top surface of the base is arc shaped and higher in a middle thereof.

4. The heat sink as claimed in claim 1, wherein the top surface of the base includes a planer part thereof, and two portions extending slantingly from opposite sides of the planer part of the top surface towards the bottom surface respectively.

5. The heat sink as claimed in claim 4, wherein the top surface and the bottom surface of the base form an intersecting line nearby the air outlet.

6. The heat sink as claimed in claim 4, wherein the top surface and the bottom surface of the base form an intersecting line nearby the air inlet.

7. The heat sink as claimed in claim 6, wherein the top surface and the bottom surface of the base form another intersecting line nearby the air outlet.

8. A heat sink comprising:
a base comprising a bottom surface configured for contacting with a heat generating component, and a top surface opposing the bottom surface, at least one of the bottom and top surfaces being arcuate-shaped to cause a thickness of the base gradually reducing from a middle thereof to two opposing lateral sides thereof;
a plurality of parallel fins extending upward from the top surface of the base;
an airflow generating device configured for providing an airflow to pass through the fins and the bottom side of the base from one of the lateral sides to the other of the lateral sides.

9. The heat sink as claimed in claim 8, wherein the top and bottom surfaces of the base both are arcuate-shaped.

10. The heat sink as claimed in claim 8, wherein said at least one of the bottom and top surfaces being arcuate-shaped comprises a flat portion located at the middle thereof and two curve portions extending from opposite sides of the flat portion.

11. The heat sink as claimed in claim 8, wherein two intersection lines are respectively connected between the top and bottom surfaces at said two opposing lateral sides.
